(19) United States
(12) Patent Application Publication
(10) Pub. No.: US 2025/0275284 A1
(43) Pub. Date: Aug. 28, 2025

(54) METHOD FOR PREPARING SMALL-WIDTH LINEAR STRUCTURE ON UPPER SURFACE OF TARGET LAYER OF LAYER STACK AND APPLICATION THEREOF

(71) Applicant: CNBM RESEARCH INSTITUTE FOR ADVANCED GLASS MATERIALS GROUP CO.,LTD., Bengbu (CN)

(72) Inventors: Yilei SHEN, Schwetzingen (DE); Marko STOELZEL, Muenchen (DE)

(21) Appl. No.: 19/203,081

(22) Filed: May 8, 2025

Related U.S. Application Data
(63) Continuation of application No. PCT/CN2023/134042, filed on Nov. 24, 2023.

(51) Int. Cl. H10F 71/00; H10F 77/20

(52) U.S. Cl. CPC H10F 71/134; H10F 77/211

(57) ABSTRACT

The present invention discloses a method for preparing a small-width linear structure on the upper surface of a target layer of a layer stack and application thereof. The method includes the steps of: acquiring the preset positions of both sides of the linear structure on the upper surface of the target layer, which are denoted as a first side position and a second side position; forming a protruding line at at least one side position by producing a plurality of protrusions at intervals along the side length direction at at least one of the first side position and the second side position of the upper surface of the target layer; and applying a liquid-type linear structure material to one side of the protruding line for deposition to obtain a linear structure confined to one side of the protruding line.

### CROSS-REFERENCE TO RELATED APPLICATIONS

This application is a continuation of International Patent Application No. PCT/CN2023/134042, filed on Nov. 24, 2023. The content of the aforementioned applications, including any intervening amendments thereto, are incorporated herein by reference.

### TECHNICAL FIELD

The present invention relates to the field of thin-film solar cell technology, and in particular, to a method for preparing a small-width linear structure on the upper surface of a target layer of a layer stack and an application thereof.

### BACKGROUND

Thin-film solar cells are of a multi-layer structure. As known to those skilled in the art, the layer structure of thin-film solar cells consists of at least a substrate, a back electrode layer, an absorber layer, a buffer/i-layer and a front electrode layer sequentially from bottom up in substrate configuration and inverted for superstrate configuration but with the same layers. For a large-area thin-film solar cell, in order to avoid high series resistance and subsequent high current loss, modules are usually designed as a series of monolithic interconnected cells. In order to implement division and series connection, P1, P2 and P3 lines are arranged on the back electrode layer, the absorber layer, the buffer layer, and the front electrode layer (as shown in FIG. 1), respectively. Specifically, the preparation method for thin-film solar cells includes the following steps:
providing a substrate;
depositing a back electrode layer on one side of the substrate;
subdividing the back electrode layer by means of a P1 line;
sequentially depositing an absorber layer and a buffer/i-layer on the back electrode layer;
synchronously subdividing the absorber layer and the buffer/i-layer by means of a P2 line;
depositing a front electrode layer on the buffer/i-layer; and
subdividing the front electrode layer by means of a P3 line.

P1 and P3 insulate the back electrode and the front electrode, and P2 serves as an electrical contact between the back electrode and the front electrode for the series connection of two adjacent cells. Since the structural area of P1/P2/P3 does not generate electricity, it is usually referred to as the “dead area” of the solar cell (as shown in FIGS. 2 and 3). The remaining area is referred to as the active area of the solar cell.

In order to optimize the power conversion efficiency and application performance of solar cells, it can be favorable to add a linear structure on the upper surface of one layer. Considering that the width and thickness of the linear structure and the coverage area of the linear structure on the surface of the layer will affect the electrical and optical characteristics of the solar cell, it is necessary to confine the positions of the two sides of the linear structure, the thickness of the linear structure, and other parameters. The object of the present invention is to provide a method for preparing a linear structure, which can conveniently control and confine the positions of the sides of the linear structure, the thickness of the linear structure, and other parameters.

In order to optimize the power conversion efficiency of solar cells, a commonly considered method is to increase the transmission of the front electrode, for example, by reducing its layer thickness and therewith increasing the generated photocurrent. However, this leads to an increase in the sheet resistance of the front electrode and therefore an increase in conduction loss. In order to reduce this conduction loss in the front electrode layer, highly conductive narrow metal grid lines can be applied on the front electrode layer to improve the related electrical conductivity, which is referred to as a metallization process for photovoltaic production. Therefore, as shown in FIGS. 3, 4 and 5, the metal grid lines G1 are applied transversely to the cell or perpendicular to P1/P2/P3 at periodic intervals. These grid lines G1 are continuously applied to the solar cell. P3 interrupts the grid lines G1 to prevent a short circuit between the front electrode of one cell and its adjacent cell.

As shown in FIG. 6, in the case of a monolithic interconnected cell, the current flowing toward the end of the cell which is collected by the metal grid lines G1 is directly connected to the back electrode of the next cell through the P2 line. The metal grid lines G1 reduce the conduction loss caused by the thinned front electrode, thus counteracting the increase of the series resistance. However, it also leads to an increase in the dead area due to the shading caused by the opaque metallic grid lines.

The area of shading of the underlying absorber layer is defined by the width and length of the metal grid lines G1. While the length of the metal grid lines G1 should not be changed in consideration of the beneficial effects of carrier collection in the metal grid lines and the thinner front electrode (increasing photocurrent without increasing series resistance), the width and thickness of the metal grid lines G1 can be optimized to reduce the area of shading, so as to increase the photocurrent and efficiency of the solar cell. The relationship between the thickness and width of the metal grid lines G1 is referred to as the aspect ratio. The series resistance of the metal grid lines G1 is determined by the specific series resistance of the material it consists of and the cross-sectional area. Therefore, in order to improve the efficiency of the solar cell, the optical shielding should be reduced by reducing the width of the metal grid lines G1, while the thickness of the metal grid lines G1 should be increased to prevent conduction loss. Generally speaking, the purpose of using the metallic grid lines G1 is to apply lines with minimal width and sufficient thickness to reduce the shading by the metal grid lines G1 and ensure a low series resistance whilst improving the generated photocurrent and improving the efficiency of the solar cell.

As shown in FIG. 6, in the case of a monolithic interconnected cell, the current is collected on the metal grid lines toward the end of the cell and needs to be evenly distributed at the beginning of the next cell. Otherwise, the front electrode and the back electrode will produce further conduction loss. Therefore, an additional metal grid line G2 can be used in the dead area. The metal grid line G2 is perpendicular to the metal grid lines G1, and is just deposited on or parallel to the P2 structural line, as shown in FIGS. 14 and 15. The purpose of applying G2 is to evenly distribute the current and reduce the electrical loss along the P2 interconnection between two adjacent cells which is caused by the high current collection of the G1 metal grid lines and their punctual connection to P2, as shown in FIGS. 16 and 17. Since G2 is arranged in the dead area, it will not cause additional light loss due to shading. In addition, it can improve the generation of photocurrent, by reflecting light to the back of a covering layer/front glass from the grid line G2 and which then can further enter the absorber layer.

Therefore, for accurate electrical and optical management in the dead area, it is necessary to accurately deposit the line G2. In addition, when G2 is deposited on the edges of P1 and P3 lines, it may lead to shunting in the active cell area. In addition, the line G2 is mechanically torn by the mechanical scribing of the P3 patterned line, or the area proposed for the laser P3 line is masked, resulting in a discontinuous P3 line and thus shunting. Generally speaking, it is very important to really confine the line G2 within the boundary of the P2 patterned line. A distinct broader G2 than P2 will increase the dead zone otherwise.

Further, in the prior art, the process method for making a metal grid, e.g. ALD (Aluminum Line Deposit) proposed by Solibro, is a method for depositing an aluminum wire structure through the combination of thermal evaporation and a mask. The resulting structure is shown in FIG. 7. The various disadvantages of the method are: 1) low throughput and yield due to the use of a mask; 2) the high cost of this special mask for the production of large-area modules; 3) high material waste due to evaporation; 4) the high workload of mask maintenance, which is the most important for the efficiency of solar cells; and 5) the limitation in the width (and aspect ratio) of the metal grid lines (the too narrow mask opening which is less than a few hundred micrometers can be easily blocked during or after use).

For example, Nice Solar adopts a screen printing method to deposit its metal grid lines. For large-area printing, screen printing is not suitable for use because it has key technical limitations. A large printed pattern may lead to low deposition accuracy and poor line shape (broader lines), particularly in the middle region of the printed area with a large size (>1 m²), which are due to the low stiffness (bending) of the central of the large screen. In addition, printing narrow lines by adopting screen printing requires a high-quality screen, e.g. a hardened and calendered stainless steel screen or a knotless screen. For full-size thin-film solar cell modules (e.g. >1 m²), those high-quality large-size screens are very difficult to manufacture (less than two suppliers in the world are able to do it) and very expensive. In addition, the screen used in the process of screen printing can be easily blocked, and is difficult to clean. In addition to the high cost of screen printing for large thin-film modules, it is also quite inflexible to change the printed pattern of grid lines when the line pitch needs to be adjusted in the production process.

Other process methods of making a metal grid, such as aerosol jet printing or dispensing, are new techniques for the metallization process, but still have the severe problem of process stability. Nozzles used for aerosol jetting and dispensers can be easily blocked by metal particles during long-term printing, leading to frequent process downtime. In addition, these two methods can simultaneously print 5 to 10 grid lines at most. For printing on a large-area thin-film module, printing needs to be performed multiple times. At present, the throughput of aerosol jet printing is very low, and it is quite difficult to further increase the number of nozzles for dispensing or aerosol jetting, because the paste/aerosol distribution along the horizontal direction in a printing head is very challenging. At present, ten nozzles are almost the bottleneck of these two techniques.

Other process methods of making a metal grid, such as the inkjet printing technique, print solvent-based ink or paste on the surface of the front electrode layer to form metal grid lines. Inkjet printing is suitable for various line shapes and forms, because it is a digital printing technique (e.g. PCT/CN2022/074345). This also makes it suitable for large-scale application, particularly in thin-film photovoltaics. One of the main disadvantages of this technique is that the composition of ink contains a small amount of metal particles and a large amount of solvent. This usually leads to wide and thin lines on the top of the front electrode of the solar cell. In addition, due to the coffee ring effect as shown in FIG. 8(a) and FIG. 8(b), the edges of the jetted ink line are thicker than the middle of the line.

In the prior art, during the making of metal grid lines on the surface of the front electrode of a solar cell, solvent-based ink or paste is generally used, and the width of the metal grid lines largely depends on the surface tension and wettability of the ink or paste, which significantly limits the use of materials as the front electrode and/or surface formation and/or surface treatment for an optimized aspect ratio. In addition, since most of the metal grid lines must be heated to remove the solvent and improve the electrical conductivity, the shape of the lines may change after the metal grid lines are deposited. Solvent-based ink or paste is composed of metal and solvent according to a ratio. In one method, only decreasing the ratio of the solvent to the metal (re-formulation) may reduce the width of lines, but this method can easily lead to the blockage of the printing head or the screen. In another method, the line width is reduced by using less material (smaller droplets), but this method will simultaneously lead to the thinning of the metal grid lines, thus increasing the series resistance. In order to overcome this problem, a multi-application solution can usually keep a small line width and increase the thickness of the metal lines. However, particular for the high speed used for high throughput in mass production, this method shows main disadvantages, because the alignment of the produced lines is crucial and the dispersion of the produced lines will occur.

### SUMMARY

In view of the problems existing in the prior art, the present invention provides a method for preparing a small-width linear structure on the upper surface of a target layer of a layer stack and an application thereof. A plurality of protrusions are produced on the sides of the linear structure to form protruding lines. The lateral positions of the linear structure can be confined by using the protruding lines, so that the linear structure can be confined unilaterally or bilaterally. Thus, the width, thickness and position of the linear structure can be limited when the linear structure is confined bilaterally, realizing the control and optimization of the shape of the linear structure; or the position of the linear structure can be confined when the linear structure is confined unilaterally, preventing the linear structure from shading a partial area or target area of a lower film layer. The technical solution of the present invention is as follows:

In a first aspect, a method for preparing a small-width linear structure on the upper surface of a target layer of a layer stack is provided, which is applied to the process of preparing a thin-film photovoltaic module, and the layer stack comprises at least two layers. The method for preparing a linear structure comprises the steps of:
acquiring the preset positions of both sides of the linear structure on the upper surface of the target layer, which are denoted as a first side position and a second side position;
forming a protruding line at at least one side position by producing a plurality of protrusions at intervals along the side length direction at at least one of the first side position and the second side position of the upper surface of the target layer; and
applying a liquid-type linear structure material to one side of the protruding line for deposition to obtain a linear structure confined to one side by the protruding line.

In some embodiments, the method for preparing a linear structure comprises:
when a plurality of protrusions are produced at intervals along the side length direction at the first side position and second side position of the upper surface of the target layer respectively to form a first protruding line and a second protruding line, applying a liquid-type linear structure material between the first protruding line and the second protruding line for deposition to obtain a linear structure confined between the first protruding line and the second protruding line, i.e. a linear structure confined bilaterally; or
when a plurality of protrusions is produced at intervals along the side length direction at one confined side position among the first side position and second side position of the upper surface of the target layer to form a third protruding line, applying a liquid-type linear structure material to one side of the third protruding line for deposition to obtain a linear structure confined to the one side of the third protruding line.

In some embodiments, the interval between two adjacent protrusions on the same protruding line is small enough, so as to prevent the linear structure material from overflowing from one side of the protruding line to the other side of the protruding line during deposition.

In some embodiments, the interval between two adjacent protrusions on the same protruding line is less than 10 microns.

In some embodiments, when the linear structure is confined bilaterally, the protrusions of the first protruding line and the protrusions of the second protruding line are asymmetrical along the central line between the first protruding line and the second protruding line.

In some embodiments, when the linear structure is confined bilaterally, the protrusions of the first protruding line and the protrusions of the second protruding line are symmetrical along the central line between the first protruding line and the second protruding line.

In some embodiments, the interval between two adjacent protrusions on the same protruding line is consistent.

In some embodiments, the interval between two adjacent protrusions on the same protruding line is inconsistent.

In some embodiments, the height of the protrusions is large enough, so as to prevent the material for the formation of the linear structure from overflowing from the protrusions during the formation of the linear structure.

In some embodiments, the height of the protrusions is determined based on the property parameters of the material for the formation of the linear structure.

In some embodiments, the property parameters of the material for the formation of the linear structure have to be chosen correctly and include the amount, viscosity and surface tension of the material.

In some embodiments, the height of the protrusions is larger than 100 nanometers.

In some embodiments, the method for producing the protrusions comprises: applying a pulsed laser meeting preset process parameters on the upper surface of the target layer by emitting the pulsed laser from above the target layer, so that the pulsed laser passes through the target layer and reaches the interface of two adjacent layers among multiple layers under the target layer, thus melting and evaporating part of the layer material at the interface between the two adjacent layers to form upward protrusions.

In some embodiments, the preset process parameters of the pulsed laser meet the following condition: the wavelength of the pulsed laser is larger than the optical band gap of the target layer but smaller than the optical band gap of at least one of the multiple layers under the target layer.

In some embodiments, among the preset process parameters of the pulsed laser, the laser power of the pulsed laser is determined based on the thickness of the target layer and the property parameters of the target layer material.

In some embodiments, the property parameters of the target layer material at least include the hardness, stiffness, tension and adhesion of the material of the front electrode layer.

In some embodiments, the method for applying the liquid-type linear structure material includes, but is not limited to, inkjet printing, aerosol jetting, screen printing and dispensing.

In a second aspect, an application of the method for preparing a linear structure is provided, comprising application in the single-pass and/or multi-pass application of a liquid-type linear structure material.

In a third aspect, based on the method for preparing a linear structure, a method for preparing metal grid lines based on an improved surface structure of a front electrode is provided, wherein the target layer is a front electrode layer, and the multiple layers under the target layer include a buffer/i-layer, an absorber layer, a back electrode layer, and a substrate, and the linear structure consists of metal grid lines located on the upper surface of the front electrode layer.

In some embodiments, the metal grid lines include a metal grid line G1 perpendicular to a P1 line, a P2 line and a P3 line and a metal grid line G2 parallel to and above the P2 line.

In some embodiments, the method for preparing the metal grid line G1 comprises:
G1(1) acquiring the preset positions of the two sides of the metal grid line G1 on the surface of the front electrode, which are denoted as a first side preset position and a second side preset position;
G1(2) producing a plurality of protrusions at intervals along the side length direction at the first side preset position and the second side preset position respectively to form a first protruding line and a second protruding line;
G1(3) applying a liquid-type metallic grid line material between the first protruding line and the second protruding line for deposition to obtain the metal grid line G1 confined between the first protruding line and the second protruding line;

The method for preparing the metal grid line G2 comprises:
G2(1) acquiring the position of the side of the P2 line close to the P3 line on the surface of the front electrode, which is denoted as a third side position;
G2(2) producing a plurality of protrusions at intervals along the side length direction at the third side position to form a third protruding line;
G2(3) applying a liquid-type metallic grid line material in the P2 line for deposition to obtain the metal grid line G2, with the side of the metal grid line G2 close to the P3 line being confined by the third protruding line.

In some embodiments, the material of the metal grid lines include, but is not limited to, metallic ink and dielectric ink.

In a fourth aspect, based on the aforementioned method for preparing metal grid lines, a method for optimizing the aspect ratio of metal grid lines based on an improved surface structure of a front electrode is provided, including: controlling the distance between a first protruding line and a second protruding line, the height of protrusions and the amount of metal grid line material, controlling the deposition width and thickness of the metal grid lines, so as to control and optimize the aspect ratio of the metal grid lines.

In a fifth aspect, based on the method for preparing metal grid lines, a method for preparing a thin-film solar cell is provided, which includes the steps of:
sequentially making a substrate, a back electrode layer, an absorber layer, a buffer/i-layer and a front electrode layer of a thin-film solar cell, or sequentially making a substrate, a front electrode layer, a buffer/i-layer, an absorber layer and a back electrode layer of a thin-film solar cell;
after the back electrode layer is made, arranging a P1 line on the back electrode layer; after the buffer/i-layer is made, arranging a P2 line on the absorber layer and the buffer/i-layer; after the front electrode layer is made, arranging a P3 line on the front electrode layer; and carrying out the division and series connection of the large-area thin-film solar cell by means of the P1 line, the P2 line and the P3 line; and
based on the method for preparing metal grid lines making a metal grid line G1 and a metal grid line G2 on the surface of the front electrode layer far from the buffer layer respectively.

### BRIEF DESCRIPTION OF DRAWINGS

FIG. 1 is a schematic cross-sectional diagram of a thin-film solar cell;

FIG. 2 is a schematic diagram of the cell width, active area and dead area of the thin-film solar cell;

FIG. 3 is a schematic cross-sectional diagram of a thin-film solar cell with a metal grid line G1;

FIG. 4 is a schematic diagram of the grid width and grid pitch of the thin-film solar cell with the metal grid line G1;

FIG. 5 is a top view of three interconnected cells with the thin-film photovoltaic module with the metal grid lines G1;

FIG. 6 is a schematic diagram of the current direction into the metal grid line G1;

FIG. 7 is a schematic diagram of carrying out a grid deposition process on a substrate by adopting thermal evaporation and a mask;

FIG. 8(a) and FIG. 8(b) is the “coffee ring” effect occurring with the inkjet printing technique;

FIG. 9 (a) and FIG. 9(b) are schematic diagrams of forming protrusions by using a pulsed laser during the preparation of the metal grid line G1;

FIG. 10(a) and FIG. 10(b) are greyscale images which are taken by a confocal microscope when two protruding lines are formed on the top of a front electrode during the preparation of the metal grid line G1, where FIG. 10(a) is a 2D image, and FIG. 10(b) is a 3D image;

FIG. 11 is a cross-sectional image of the two protruding lines formed on the top of the front electrode during the preparation of the metal grid line G1;

FIG. 12(a) and FIG. 12(b) are schematic diagrams of the confining effect of two protrusions on the first protruding line and the second protruding line with a liquid-type metallic grid line material inside;

FIG. 13(a), FIG. 13(b) and FIG. 13(c) are schematic diagrams of possible position distributions of the protrusions on the first protruding line and the second protruding line;

FIG. 14 is a cross-sectional diagram of the layer stack of a thin-film solar cell with the two metal grid lines G1 and G2;

FIG. 15 is a top view of the thin-film solar cell with the the two metal grid lines G1 and G2;

FIG. 16 is a top view of three interconnected cells with the thin-film photovoltaic module with the two metal grid lines G1 and G2;

FIG. 17 is a schematic diagram of the current direction at the two metal grid lines G1 and G2;

FIG. 18(a) and FIG. 18(b) are schematic diagrams of producing protrusions of a third protruding line by using a pulsed laser;

FIG. 19(a) and FIG. 19(b) are pseudo-3D greyscale images of the third protruding line taken by a confocal microscope, where FIG. 19(a) is a pseudo-3D greyscale image of the third protruding line capable of confining the metal grid line G2 unilaterally, and FIG. 19(b) is a pseudo-3D greyscale image of a groove caused by the ablation of the buffer layer and the front electrode due to a too high laser power applied whilst forming the aforementioned protrusions;

FIG. 20 is a pseudo-2D greyscale image of the third protruding line;

FIG. 21 is a cross-sectional image of the protrusions of the third protruding line;

FIG. 22(a) and FIG. 22(b) are schematic diagrams of depositing material of the metal grid line G2 on a P2 line after the formation of the third protruding line, where FIG. 22(a) is a schematic diagram of applying the material of the metal grid line G2 on the P2 line after the formation of the third protruding line, and FIG. 22(b) is a schematic diagram of one side of the metal grid line G2 close to P3 being confined after the deposition of the material of the metal grid line G2;

FIG. 23(a) and FIG. 23(b) are schematic diagrams of the position distributions of the protrusions on the third protruding line.

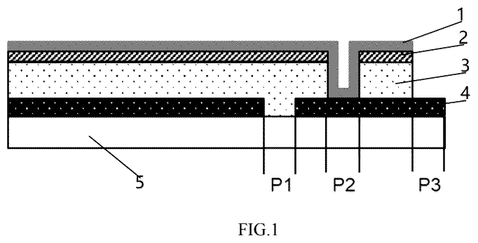

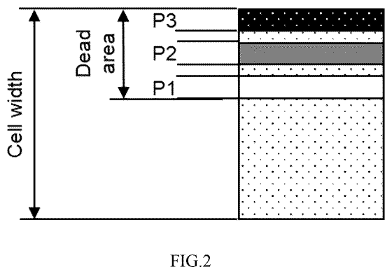

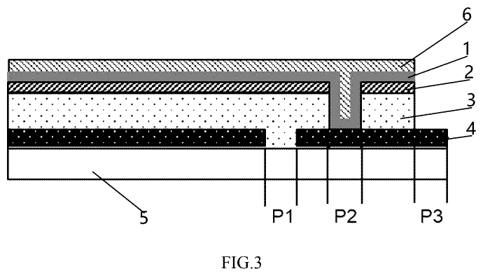

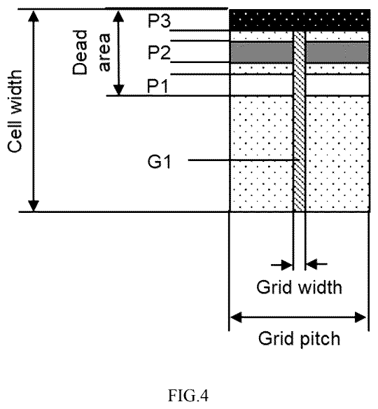

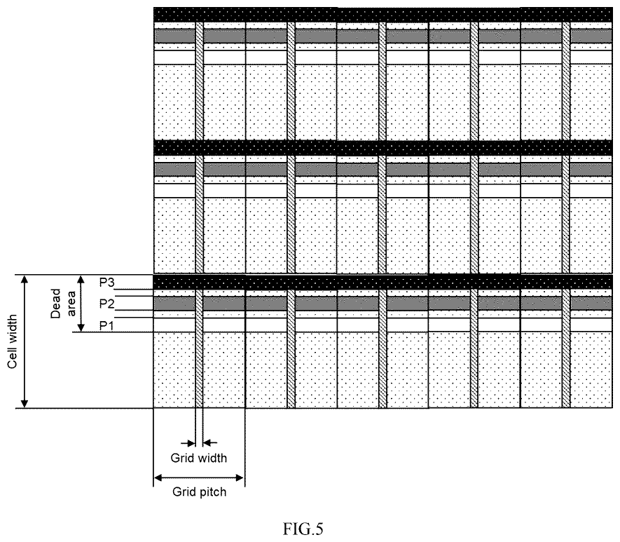

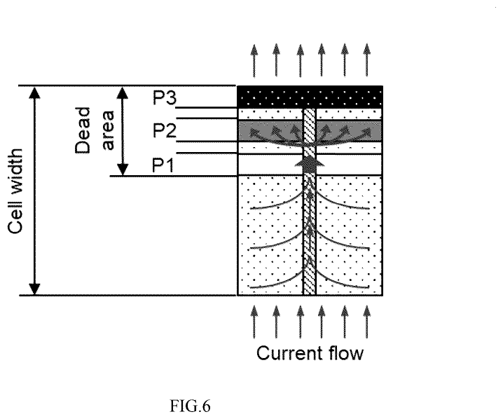

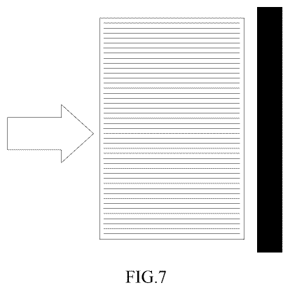

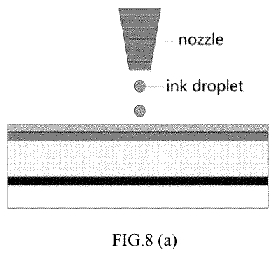

### REFERENCE NUMERALS

1. Front electrode layer; 2. Buffer layer; 3. Absorber layer; 4. Back electrode layer, 5. Substrate; 6. Metal grid line G1.

### DESCRIPTION OF EMBODIMENTS

The present invention is applied to the process for preparing a thin-film photovoltaic module, and the thin-film photovoltaic module consists of a layer stack. For example, the thin-film photovoltaic module sequentially includes a substrate, a back electrode layer, an absorber layer, a buffer/i-layer and a front electrode layer from bottom up. When a small-width linear structure (e.g. metal grid line) needs to be prepared on the upper surface of one layer in the process of preparing a thin-film photovoltaic module, considering that it is required to control and limit the width, thickness and position of the small-width linear structure, the present application provides a method for preparing a small-width linear structure on the upper surface of a target layer of a layer stack, which is applied to the process of preparing a thin-film photovoltaic module, and the layer stack includes at least two layers. The method for preparing a linear structure includes the steps of:
acquiring the preset positions of both sides of the linear structure on the upper surface of the target layer, which are denoted as a first side position and a second side position;
forming a protruding line at at least one side position by producing a plurality of protrusions at intervals along the side length direction at at least one of the first side position and the second side position of the upper surface of the target layer; and
applying a liquid-type linear structure material to one side of the protruding line for deposition to obtain a linear structure confined by one side of the protruding line.

In the embodiments of the present application, a plurality of protrusions is produced on the side of the linear structure to form a protruding line, and the side position of the linear structure is confined by the protruding line. It can be understood that if the first protruding line is formed at the first side position, when the liquid-type linear structure material is applied to the side of the first protruding line close to the second side position, the first side of the linear structure obtained by deposition is confined to the area where the first protruding line is close to the second side position, and the first side of the linear structure obtained by deposition will not reach the area where the first protruding line is far from the second side, that is, the protruding line confines the side position of the deposited liquid-type linear structure material. It can be understood that when a first protruding line and a second protruding line are formed at the first side position and the second side position respectively, a linear structure with both side positions confined can be obtained by applying the liquid-type linear structure material between the first protruding line and the second protruding line, that is, a linear structure confined between the first protruding line and the second protruding line can be obtained by deposition. When a protruding line (denoted as a third protruding line) is formed at one of the first side position and the second side position, the liquid-type linear structure material is applied to one side of the third protruding line, and one side of the linear structure obtained by deposition is confined to the one side of the third protruding line without reaching the other side of the third protruding line.

Further, when a plurality of protrusions is produced at intervals along the side length direction at the first side position and second side position of the upper surface of the target layer respectively to form a first protruding line and a second protruding line, the liquid-type linear structure material is applied between the first protruding line and the second protruding line for deposition to obtain a linear structure confined between the first protruding line and the second protruding line, i.e. a linear structure confined bilaterally; or
when a plurality of protrusions is produced at intervals along the side length direction at one confined side position among the first side position and second side position of the upper surface of the target layer to form a third protruding line, the liquid-type linear structure material is applied to one side of the third protruding line for deposition to obtain a linear structure confined to the one side of the third protruding line, i.e. a linear structure confined unilaterally.

In the embodiments of the present application, the linear structure can be bilaterally or unilaterally confined by the protruding lines formed by a plurality of closely adjacent protrusions.

It can be understood that according to the method for preparing a small-width linear structure on the upper surface of a target layer of a layer stack, aiming at the characteristic that the surface tension, wettability and other properties of the linear structure material and the shape of the lines formed by the deposited the linear structure material are not easy to control when the liquid-type linear structure material is adopted to make the linear structure during the mass production of thin-film solar cells, a plurality of upward protrusions are produced on the upper surface of the target layer of the thin-film solar cell, and the protruding lines formed by the plurality of densely distributed protrusions are utilized to surround the edges of the deposition area of the linear structure material, so as to confine the deposition area of the linear structure material, realizing the control of the line shape of the linear structure. Then, by adjusting the positions of the protrusions, i.e. changing the position of the protruding line, at least one side position of the linear structure can be confined, and the width of the lines of the linear structure can be changed by confining both side positions of the linear structure. Of course, if the amount of the linear structure material is fixed, a decrease in the width of the lines of the linear structure will also lead to an increase in the thickness of the lines of the linear structure. Alternatively, if the width of the lines of the linear structure is unchanged, the thickness of the lines of the linear structure can also be increased by increasing the height of the protrusions by e.g. the amount of the linear structure material applied.

It can be understood that after a plurality of upward protrusions are produced on the upper surface of the target layer of the thin-film solar cell, if the distance between two adjacent protrusions (a protrusion A and a protrusion B) is very small, the linear structure material cannot be accommodated between the two adjacent protrusions (the protrusion A and the protrusion B), so a protruding line can be formed by connecting the plurality of protrusions A and B (the distance between the protrusions A and B is very small) together to limit the linear structure material from overflowing from the position of the protruding line, realizing the confinement of the position of at least one side of the linear structure.

If the distance between two adjacent protrusions (a protrusion C and a protrusion D) is large and a “valley” is formed between the protrusion C and the protrusion D, the linear structure material can be accommodated between the two adjacent protrusions (the protrusion C and the protrusion D). On this basis, ensuring that the height of the protrusion C and the protrusion D is high enough, the width of the deposited linear structure material between the protrusions C and D can be freely controlled by adjusting the distance between the protrusions C and D. Therefore, the width of the lines of the linear structure can be changed by changing the distance between the protrusions.

A plurality of protrusions A and B (the distance between the protrusions A and B is very small) are connected together to form a protruding line, which can be used to limit the metal grid line material from overflowing from the protruding line. When the plurality of protruding lines is used in combination, the area between adjacent or close protruding lines can accommodate the linear structure material.

It can be understood that the linear structure may be a straight line or other shapes, and linear structures with different shapes can be formed by deposition only by adjusting the shape of the protruding lines. In the embodiments of the present application, the linear structure which is a straight line is taken as an example for illustration.

Specifically, the method for confining a linear structure bilaterally or unilaterally in the embodiments of the present application includes the following steps:
(Step 1) the preset position of the linear structure on the upper surface of the target layer is determined, the preset positions of both sides of the linear structure on the upper surface of the target layer are determined in combination with the preset width of the linear structure, denoted as a first side preset position and a second side preset position, and it can be understood that the preset width is a preferred value meeting the width of the linear structure, which is determined before the linear structure is made; and therefore the distance between the first side preset position and the second side preset position is a preferred width of the linear structure;
(Step 2) when the two side positions of the linear structure need to be confined, a plurality of protrusions are produced at intervals along the side length direction at the first side preset position and the second side preset position respectively to form a first protruding line and a second protruding line; a linear structure material is applied between the first protruding line and the second protruding line, and the area between the first protruding line and the second protruding line is the area where the linear structure is located;
(Step 3) when one side position of the linear structure needs to be confined, a plurality of protrusions are produced at intervals along the side length direction at one confined side position among the first side preset position and the second side preset position to form a third protruding line; and a liquid-type linear structure material is applied to one side of the third protruding line for deposition to obtain a linear structure confined to the one side of the third protruding line.

Further, for the first protruding line, the second protruding line and the third protruding line in Steps 1 to 3 above, the interval between two adjacent protrusions on the same protruding line is small enough, so as to prevent the linear structure material from overflowing from one side of the protruding line to the other side of the protruding line during deposition.

It can be understood that it is required by both the bilateral confinement realized by the first protruding line and the second protruding line and the unilateral confinement realized by the third protruding line that when the linear structure material is applied to one side of a protruding line, the linear structure material will not overflow to the other side of the protruding line after being deposited. Specifically, if the linear structure is confined bilaterally by the first protruding line and the second protruding line, while the interval between two adjacent protrusions on the first protruding line is small enough, the interval between two adjacent protrusions on the second protruding line is small enough, so as to prevent the linear structure material from overflowing out of the area between the first protruding line and the second protruding line during deposition. If the linear structure is confined unilaterally by the third protruding line, the interval between two adjacent protrusions on the third protruding line is small enough, so as to prevent the linear structure material from overflowing from one side of the third protruding line to the other side of the third protruding line during deposition.

In an alternative embodiment, the interval between two adjacent protrusions on the same protruding line is less than 10 microns. That is, the interval between two adjacent protrusions on the first protruding line is less than 10 microns, and the interval between two adjacent protrusions on the second protruding line is less than 10 microns. In some embodiments, the interval between two adjacent protrusions on the same protruding line is a few microns.

In an embodiment, when the linear structure is confined bilaterally, the protrusions of the first protruding line and the protrusions of the second protruding line are asymmetrical along the central line between the first protruding line and the second protruding line.

In another embodiment, when the linear structure is confined bilaterally, the protrusions of the first protruding line and the protrusions of the second protruding line are symmetrical along the central line between the first protruding line and the second protruding line.

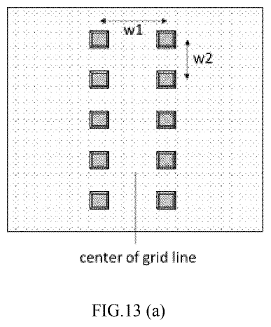

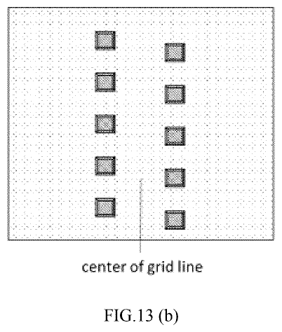

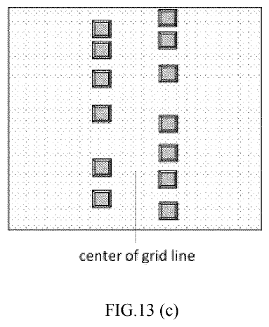

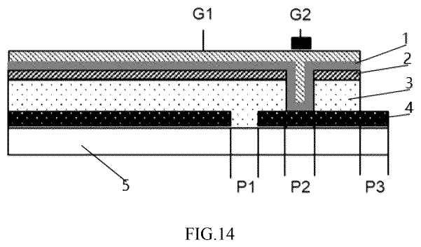

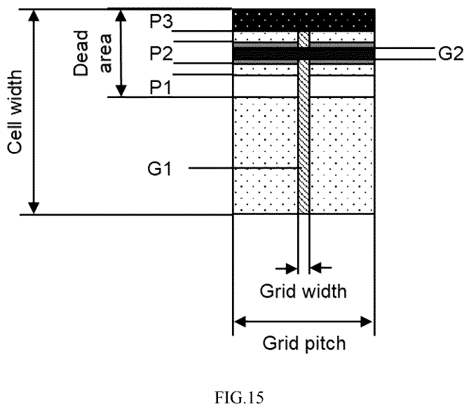

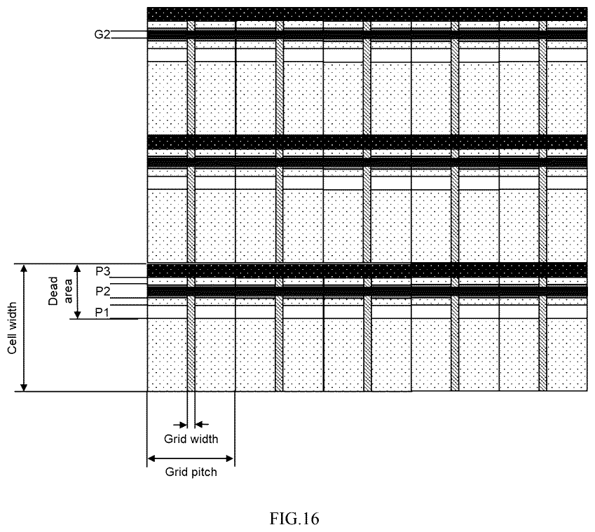

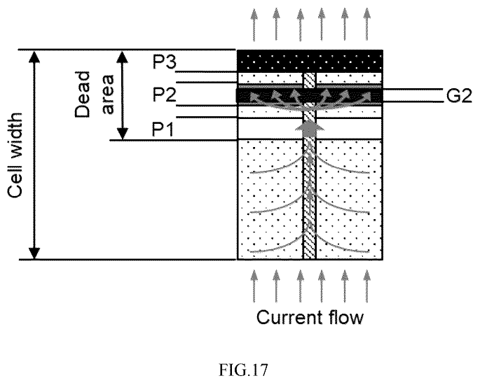

Specifically, referring to FIG. 13(a), FIG. 13(b) and FIG. 13(c), when the linear structure is confined bilaterally, in one embodiment, the distribution interval between the protrusions of the first protruding line corresponds to that of the second protruding line, that is, the distribution interval between the protrusions of the first protruding line is related to that of the second protruding line. In another embodiment, the distribution interval between the protrusions of the first protruding line may not correspond to that of the second protruding line, that is, the distribution interval between the protrusions of the first protruding line is not related to that of the second protruding line. There is a central line between the first protruding line and the second protruding line, and one protrusion on the first protruding line and one protrusion on the second protruding line can be symmetrical about the central line (as shown in FIG. 13(a)). Of course, one protrusion on the first protruding line and one protrusion on the second protruding line may be asymmetrical about the central line (as shown in FIGS. 13(b) and 13(c)).

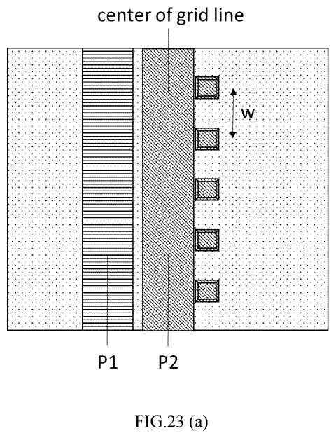

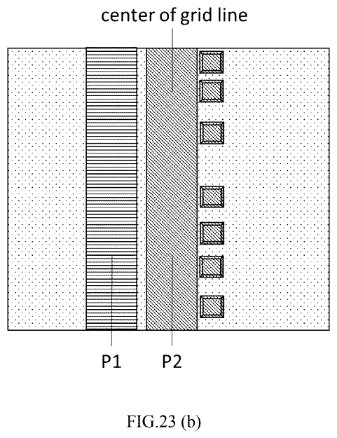

In addition, in one embodiment, the interval between two adjacent protrusions on the same protruding line is consistent. That is, when the linear structure is confined bilaterally, the interval between two adjacent protrusions on the first protruding line is consistent and/or the interval between two adjacent protrusions on the second protruding line is consistent (as shown in FIG. 13(a) and FIG. 13(b)). When the linear structure is confined unilaterally, the interval between two adjacent protrusions on the third protruding line is consistent, as shown in FIG. 23(a).

In another embodiment, the interval between two adjacent protrusions on the same protruding line is inconsistent. That is, when the linear structure is confined bilaterally, the interval between two adjacent protrusions on the first protruding line is inconsistent and/or the interval between two adjacent protrusions on the second protruding line is inconsistent (as shown in FIG. 13(c)). When the linear structure is confined unilaterally, the interval between two adjacent protrusions on the third protruding line is inconsistent, as shown in FIG. 23(b).

In a word, the distribution intervals between the protrusions of the different protruding lines have no influence on each other, as long as the interval between two adjacent protrusions on the same protruding line is small enough to prevent the linear structure material from overflowing from one side of the protruding line to the other side of the protruding line during deposition.

In order to prevent the linear structure material from overflowing from one side of a protruding line to the other side of the protruding line during deposition, i.e. in order to prevent the linear structure material from overflowing from one side of protrusions to the other side of the protrusions during deposition, there is also a requirement on the height of the protrusions. In an embodiment, the height of the protrusions is required to be large enough to prevent the material for the formation of the linear structure from overflowing from the protrusions during the formation of the linear structure. In another embodiment, the required height of the protrusions is determined based on the property parameters of the linear structure material. For example, the required height of the protrusions is determined based on the amount, viscosity and surface tension of the linear structure material, so as to prevent the linear structure material from overflowing the protrusions. In another embodiment, the height of the protrusions is required to be greater than 100 nanometers, and generally speaking, the formed protrusions usually have a height ranging from several hundred nanometers to micrometers.

Next, the method for producing protrusions will be illustrated.

The method for producing protrusions on a first protruding line, a second protruding line and a third protruding line includes: applying a pulsed laser meeting preset process parameters on the upper surface of a target layer by emitting the pulsed laser from above the target layer, so that the pulsed laser passes through the target layer and reaches the interface of two adjacent layers among multiple layers under the target layer, thus melting and evaporating part of layer material at the interface between the two adjacent layers to form upward protrusions.

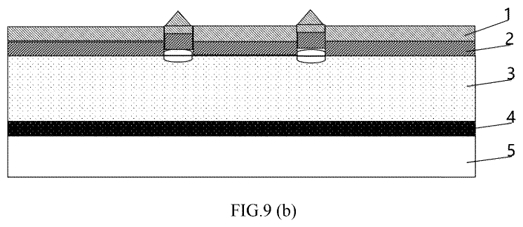

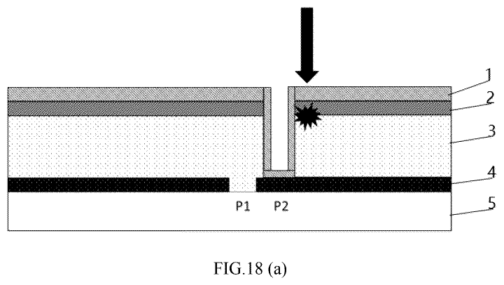

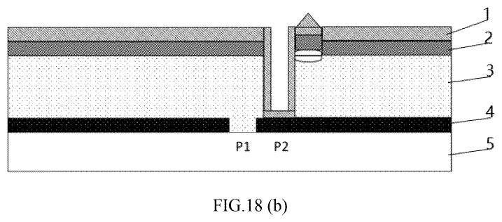

As shown in FIG. 9 (a), FIG. 9(b), FIG. 18 (a) and FIG. 18(b), the pulsed laser is applied to the upper surface of the target layer to pass through the target layer and reach the interface between two of the multiple layers under the target layer, so that part of the layer material is melted and evaporated at the interface between the two adjacent layers to form upward protrusions, thus realizing the formation of protrusions on the upper surface of the target layer.

It should be noted that the preset process parameters of the pulsed laser need to be set reasonably, which include the wavelength, power, application time, application frequency, speed and beam diameter of the pulsed laser. The adjustment of the wavelength and the power of the pulsed laser will be taken as an example for illustration below.

The wavelength of the pulsed laser is larger than the optical band gap of the target layer and smaller than the optical band gap of the material of at least one of the multiple layers under the target layer, so that the pulsed laser can pass through the target layer and stop at any layer under the target layer, and the pulsed laser will not be absorbed by the layer through which it passes, but will be absorbed at the interface where it stops, resulting in the melting and evaporation of part of the material at the interface to form upward protrusions.

For the power of the pulsed laser, it is necessary to adjust the power of the pulsed laser with the goal of forming upward protrusions on the upper surface of the target layer. When the power of the pulsed laser is too low, it will only lead to local heating, failing to form protrusions. Excessive power will cause the layer through which the pulsed laser passes to be completely ablated, forming holes instead of upward protrusions.

Specifically, the laser power of the pulsed laser is adjusted according to the thickness of the target layer and the property parameters of the material of the target layer. For example, the laser power of the pulsed laser is determined according to the hardness, stiffness, tension, adhesion and other property parameters of the material of the front electrode layer.

In the present invention, the method for applying the liquid-type linear structure material includes, but is not limited to, inkjet printing, aerosol jetting, screen printing and dispensing.

The present invention provides a method for preparing a small-width linear structure on the upper surface of a target layer of a layer stack, which is applied to the process for preparing a thin-film photovoltaic module. The method can be applied to the preparation of a thin-film photovoltaic module with substrate and superstrate structures and the preparation of CIGS, CdTe and perovskite-type thin-film photovoltaic modules for example.

The method for preparing a small-width linear structure on the upper surface of a target layer of a layer stack according to the present invention can also be applied to the single-pass and/or multi-pass application of a liquid-type linear structure material.

A linear structure which consists of metal grid lines will be taken as an example for illustration below. In the present invention, a metal grid line G1 needs to be made. In order to control and optimize the shape (including width and thickness parameters) of the metal grid line G1 on the surface of a front electrode to realize the optimization of the aspect ratio of the metal grid line G1, it is necessary to first produce two protruding lines at the two side positions of the metal grid line G1 on the surface of the front electrode, and a metal grid line material is accommodated in the area between the two protruding lines for deposition to form the metal grid line G1. Because a metal grid line G2 needs to be made in the present invention, in order to control and confine the side of the metal grid line G2 close to a P3 line from covering or being split by the P3 line, it is necessary to produce a third protruding line on the side of a P2 line close to the P3 line on the surface of the front electrode, so that the side of the deposited material of the metal grid line G2 close to the P3 line will not overflow from the third protruding line, limiting the position of the side of the metal grid line G2 close to the P3 line from reaching the P3 line.

Specifically, based on the method for preparing a small-width linear structure on the upper surface of a target layer of a layer stack, a method for preparing metal grid lines based on an improved surface structure of a front electrode is provided, the target layer is a front electrode layer, and the multiple layers under the target layer include a buffer/i-layer, an absorber layer, a back electrode layer, and a substrate, and the linear structure consists of metal grid lines located on the upper surface of the front electrode layer. The metal grid lines include a metal grid line G1 perpendicular to a P1 line, a P2 line and a P3 line and a metal grid line G2 parallel to the P2 line and located above of the P2 line. It can be understood that in the embodiments of the present application, it is necessary to control and optimize the width and thickness of the metal grid line G1, so as to optimize the aspect ratio of the metal grid line G1, that is, it is necessary to confine the two side positions of the metal grid line G1. In the embodiments of the present application, it is necessary to confine a single side position of the metal grid line G2, so as to prevent the side of the metal grid line G2 close to the P3 line from reaching the P3 line, that is, it will not cover or be split by the P3 line. Specifically, the method for preparing the metal grid line G1 includes:
G1(1) acquiring the preset positions of the two sides of the metal grid line G1 on the surface of the front electrode, which are denoted as a first side preset position and a second side preset position;
G1(2) producing a plurality of protrusions at intervals along the side length direction at the first side preset position and the second side preset position respectively to form a first protruding line and a second protruding line;
G1(3) applying a liquid-type metallic grid line material between the first protruding line and the second protruding line for deposition to obtain the metal grid line G1 confined between the first protruding line and the second protruding line;

The method for preparing the metal grid line G2 includes:
G2(1) acquiring the position of the side of the P2 line close to the P3 line on the surface of the front electrode, which is denoted as a third side position;
G2(2) producing a plurality of protrusions at intervals along the side length direction at the third side position to form a third protruding line;
G2(3) applying a liquid-type metallic grid line material in the P2 line for deposition to obtain the metal grid line G2, with the side of the metal grid line G2 close to the P3 line being confined by the third protruding line.

It can be understood that the width and thickness of the metal grid line G1 are controlled through steps G1(1), G1(2) and G1(3) above. Specifically, in step G1(1), the preset position of the metal grid line G1 on the surface of the front electrode is determined, and the preset positions of both sides of the metal grid line G1 on the surface of the front electrode are determined in combination with the preset width of the metal grid line G1, recorded as a first side preset position and a second side preset position. It can be understood that the preset width is a preferred value of the width of the metal grid line meeting the aspect ratio condition of the metal grid line, which is determined before the making of the metal grid line; and therefore the distance between the first side preset position and the second side preset position is a preferred width of the metal grid line. In step G1(3), the method for applying the metal grid line material may be inkjet printing, aerosol jetting, screen printing, dispensing, etc., and inkjet printing is the preferred technique.

In the process of preparing the metal grid lines G1 and G2, the method for producing the protrusions is as follows: a pulsed laser in combination with preset process parameters is applied to the surface of the front electrode layer far from the buffer layer, so that at least the front electrode layer protrudes upward at positions where the laser is applied. Specifically, in the present invention, the pulsed laser is applied to the surface of the front electrode layer, so that the pulsed laser passes through the front electrode layer from above the thin-film solar cell until one of the underlying layers, namely the buffer/i-layer, the absorber layer, the back electrode layer and the substrate, absorbs the laser radiation and the melting and evaporation of part of the layer material will occur when the pulsed laser is trying to pass through the interface where it stops, thus forming upward protrusions at the positions where the pulsed laser is applied. The preset process parameters of the pulsed laser need to be set reasonably, including the wavelength, power, application time, application frequency, speed and beam diameter of the pulsed laser. For example, in the embodiments of the present application, the wavelength of the pulsed laser applied on the upper surface of the front electrode layer needs to be larger than the optical band gap of the front electrode layer, so that the pulsed laser can pass through the front electrode layer, while the wavelength of pulsed laser is smaller than the optical band gap of at least one of the buffer/i-layer, the absorber layer and the back electrode layer. For example, if the wavelength of the pulsed laser is larger than the optical band gaps of the front electrode layer and the buffer/i-layer and smaller than the optical band gap of the absorber layer, the laser passes through the front electrode layer and the buffer/i-layer and is absorbed when it reaches the interface between the buffer layer and the absorber layer, resulting in melting and evaporation of part of the material at the interface between the absorber layer and the buffer/i-layer leading to protrusions upward in the layer stack in the direction of the front electrode.

For the power of the pulsed laser, it is necessary to determine the power of the pulsed laser with the goal of forming upward protrusions on the surface of the front electrode layer. When the power of the pulsed laser is too low, it will only lead to local heating, failing to form protrusions. Excessive power will cause the buffer/i-layer and the front electrode layer to be ablated completely, just as it is used for example to scribe the laser P3 line, which will lead to the widening of the lines and the increase of series resistance, because the area of interconnection between a metal grid line and the front electrode is greatly reduced (up to the thickness of the front electrode layer). Specifically, the laser power of the pulsed laser is determined according to the thickness of the front electrode layer and the property parameters of the material of the front electrode layer. For example, the laser power of the pulsed laser is determined according to the hardness, stiffness, tension, adhesion and other property parameters of the material of the front electrode layer.

For example, in the process of preparing the metal grid lines G1 and G2, the process parameters of the pulsed laser used to form protrusions may be as follows: for CIGS with 750 nm of AZO (front electrode) thickness and 65 nm of ZnOS (buffer) thickness, the laser power window is between 150 mW and 250 mW, the wavelength is 1064 nm, the laser pulse width is 15 ps, the repetition frequency is 500 kHz, the processing speed is 10800 mm/min, and the beam diameter is about 20 μm.

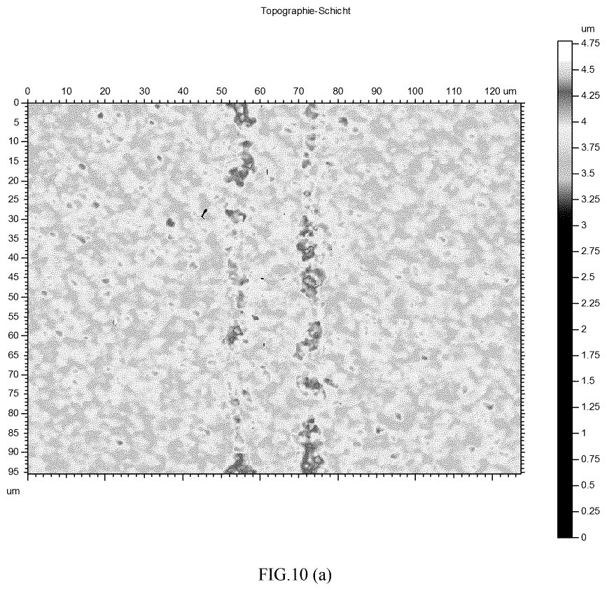

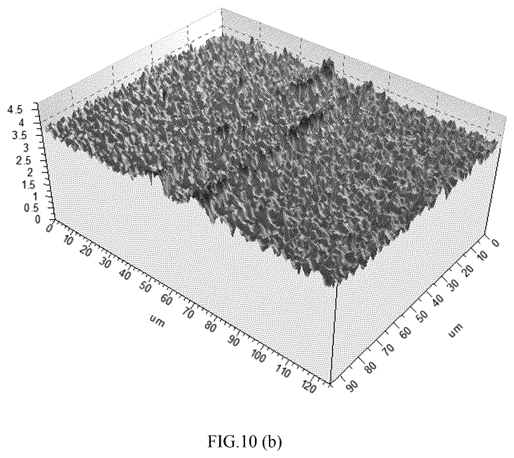

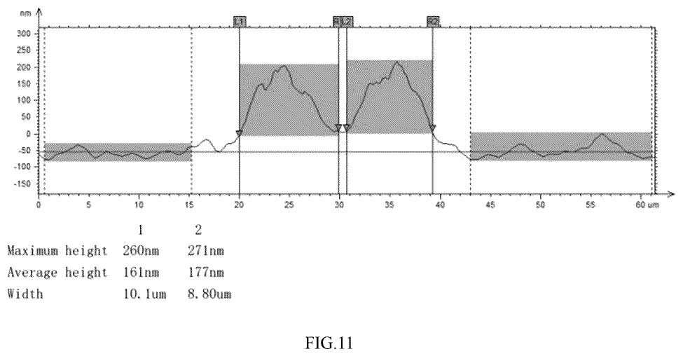

FIG. 10(a) and FIG. 10(b) show microscopic images of the first protruding line and the second protruding line (the distance between the first protruding line and the second protruding line is 20 microns) in the process of preparing the metal grid line G1. FIG. 11 shows cross-sectional images of the first protruding line and the second protruding line (the distance between the first protruding line and the second protruding line is 10 microns). Since the width of a single protrusion on the first protruding line and the second protruding line is in a range of about 10 microns, the distance between the first protruding line and the second protruding line should be more than 10 microns, so that the material of the metal grid line G1 can be accommodated between the first protruding line and the second protruding line to form the metal grid line G1 between the first protruding line and the second protruding line.

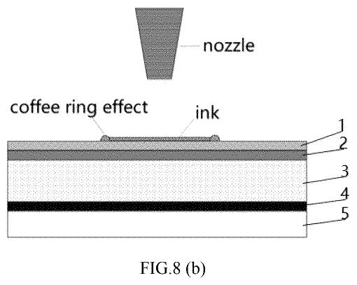

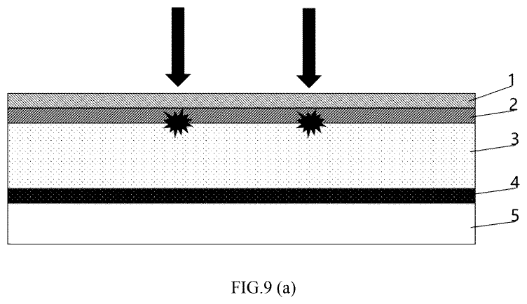

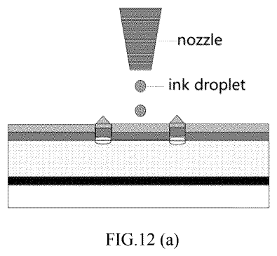

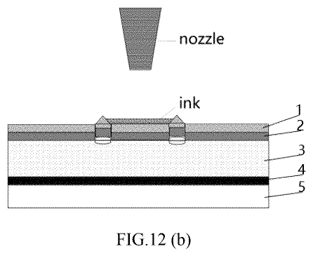

Referring to FIG. 12(a) and FIG. 12(b), when the material of the metal grid line G1 is confined between two protrusions, the material of the metal grid line G1 is filled in the space between the two protrusions, and the coffee ring effect as shown in FIG. 8(a) and FIG. 8(b) is also avoided.

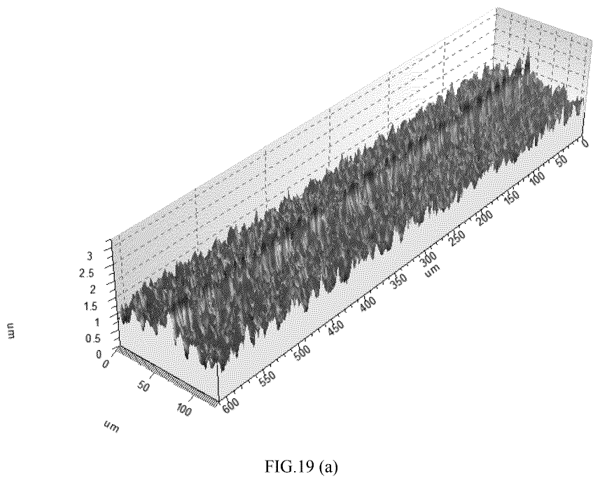

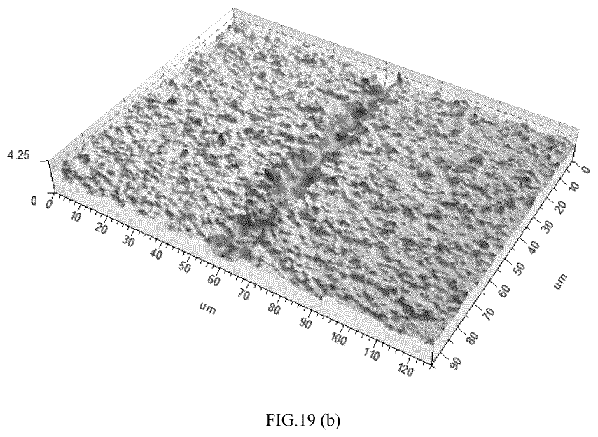

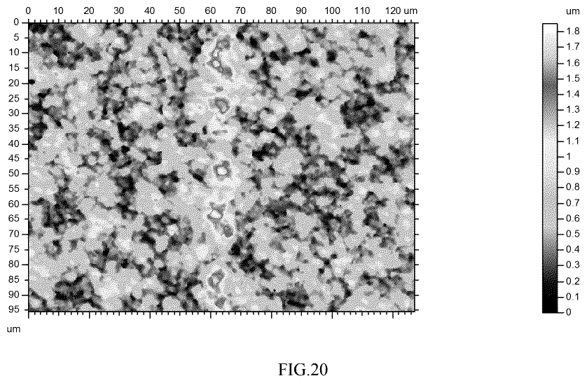

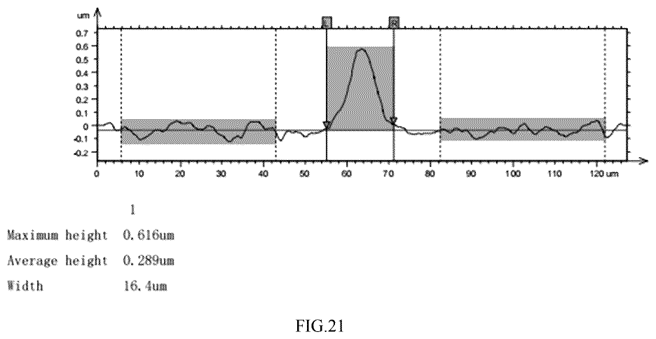

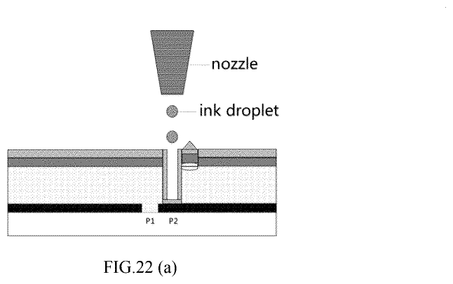

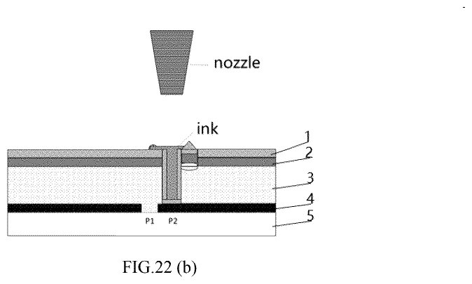

FIG. 18(a) and FIG. 18(b) show schematic diagrams of producing protrusions of a third protruding line by using a pulsed laser in the process of preparing a metal grid line G2. FIG. 19(a) and FIG. 19(b) show pseudo-3D greyscale images of the third protruding line in the process of preparing the metal grid line G2, where FIG. 19(a) shows a pseudo-3D greyscale image of the unilateral confinement of the metal grid line G2 by the formed third protruding line, and FIG. 19(b) is a pseudo-3D greyscale image showing the case when the buffer/i-layer and the front electrode will be ablated when the laser power is too high, thereby producing grooves. FIG. 20 shows a pseudo 2D greyscale image of the third protruding line for realizing unilateral confinement, and FIG. 21 is a cross-sectional image of the protrusion of the third protruding line, showing the maximum height, average height and width of the protrusion of the third protruding line. FIG. 22(a) and FIG. 22(b) show schematic diagrams of depositing a material of the metal grid line G2 on a P2 line after the formation of the third protruding line, where FIG. 22(a) shows a schematic diagram of applying the material of the metal grid line G2 on the P2 line after the formation of the third protruding line, and FIG. 22(b) shows a schematic diagram of one side close to P3 being confined after the deposition of the material of the metal grid line G2.

It should be noted that the material of the metal grid lines includes, but is not limited to, metallic ink and dielectric ink.

Based on the aforementioned method for preparing metal grid lines based on an improved surface structure of a front electrode, the present invention further provides a method for optimizing the aspect ratio of metal grid lines, including: by controlling the distance between a first protruding line and a second protruding line, the height of protrusions and the amount of metal grid line material, controlling the deposition width and thickness of metal grid lines, so as to control and optimize the aspect ratio of the metal grid lines.

Based on the aforementioned method for preparing metal grid lines based on an improved surface structure of a front electrode, a method for preparing a thin-film solar cell is provided, which includes the steps of:

The process of manufacturing photovoltaic modules: when using substrate approach to prepare photovoltaic modules, sequentially making a substrate, a back electrode layer, an absorber layer, a buffer/i-layer and a front electrode layer of a thin-film solar cell; when using the superstrate structure approach to prepare photovoltaic modules, sequentially using a substrate, a front electrode layer, a buffer/i-layer, an absorber layer and a back electrode layer of a thin-film solar cell; This process includes the production of P1 line, P2 line, P3 line, after the back electrode layer is made, arranging a P1 line on the back electrode layer; after absorber layer and the buffer/i-layer is made, arranging a P2 line on the absorber layer and the buffer/i-layer; after the front electrode layer is made, arranging a P3 line on the front electrode layer; and therewith carrying out the division and series connection of the large-area thin-film solar cell by means of the P1 line, the P2 line and the P3 line; and

Preparation process of the metal grid line G1 and G2: based on the aforementioned method for preparing metal grid lines, making a metal grid line G1 and a metal grid line G2 on the surface of the front electrode layer far from the buffer layer respectively.

The present invention is not limited to the aforementioned specific embodiments, and various changes which are made by those of ordinary skill in the art from the above idea without creative labor shall fall within the protection scope of the present invention.

What is claimed is:

1. A method for preparing a small-width linear structure on the upper surface of a target layer of a layer stack, applied to the process of preparing a thin-film photovoltaic module, and the layer stack comprising at least two layers, wherein the method for preparing a linear structure comprises the steps of:
acquiring the preset positions of both sides of the linear structure on the upper surface of the target layer, which are denoted as a first side position and a second side position;
forming a protruding line at at least one side position by producing a plurality of protrusions at intervals along the side length direction at at least one of the first side position and the second side position of the upper surface of the target layer; and
applying a liquid-type linear structure material to one side of the protruding line for deposition to obtain a linear structure confined to one side by the protruding line.

2. The method for preparing a linear structure according to claim 1, wherein
when a plurality of protrusions are produced at intervals along the side length direction at the first side position and second side position of the upper surface of the target layer respectively to form a first protruding line and a second protruding line, applying a liquid-type linear structure material between the first protruding line and the second protruding line for deposition to obtain a linear structure confined between the first protruding line and the second protruding line, i.e. a linear structure confined bilaterally; or
when a plurality of protrusions is produced at intervals along the side length direction at one confined side position among the first side position and second side position of the upper surface of the target layer to form a third protruding line, applying a liquid-type linear structure material to one side of the third protruding line for deposition to obtain a linear structure confined to the one side by the third protruding line.

3. The method for preparing a linear structure according to claim 1, wherein the interval between two adjacent protrusions on the same protruding line is small enough, so as to prevent the linear structure material from overflowing from one side of the protruding line to the other side of the protruding line during deposition, the interval between two adjacent protrusions on the same protruding line is less than 10 microns.

4. The method for preparing a linear structure according to claim 1, wherein when the linear structure is confined bilaterally, the protrusions of the first protruding line and the protrusions of the second protruding line are asymmetrical along the central line between the first protruding line and the second protruding line, or, when the linear structure is confined bilaterally, the protrusions of the first protruding line and the protrusions of the second protruding line are symmetrical along the central line between the first protruding line and the second protruding line.

5. The method for preparing a linear structure according to claim 1, wherein the interval between two adjacent protrusions on the same protruding line is consistent, or, the interval between two adjacent protrusions on the same protruding line is inconsistent.

6. The method for preparing a linear structure according to claim 1, wherein the height of the protrusions is large enough, so as to prevent the material for the formation of the linear structure from overflowing from the protrusions during the formation of the linear structure, the height of the protrusions is determined based on the property parameters of the material for the formation of the linear structure, the property parameters of the material for the formation of the linear structure at least include the amount, viscosity and surface tension of the material.

7. The method for preparing a linear structure according to claim 6, wherein the height of the protrusions is greater than 100 nanometers.

8. The method for preparing a linear structure according to claim 1, wherein the method for producing the protrusions comprises: applying a pulsed laser in combination with preset process parameters on the upper surface of the target layer by emitting the pulsed laser from above the target layer, so that the pulsed laser pulses pass through the target layer and reach the interface of two adjacent layers among multiple layers under the target layer, thus melting and evaporating part of the layer material at the interface between the two adjacent layers to form upward protrusions, the preset process parameters of the pulsed laser meet the following condition: the wavelength of the pulsed laser is larger than the optical band gap of the target layer but smaller than the optical band gap of at least one of the multiple layers under the target layer, among the preset process parameters of the pulsed laser, the laser power of the pulsed laser is determined based on the thickness of the target layer and the property parameters of the target layer material, the property parameters of the target layer material at least include the hardness, stiffness, tension and adhesion of the material of the front electrode layer.

9. The method for preparing a linear structure according to claim 1, wherein the method for applying the liquid-type linear structure material includes, but is not limited to, inkjet printing, aerosol jetting, screen printing and dispensing.

10. An application of the method for preparing a linear structure according to claim 1, comprising application in the single-pass and/or multi-pass application of a liquid-type linear structure material.

11. A method for preparing metal grid lines based on an improved surface structure of a front electrode based on the method for preparing a linear structure according to claim 1, wherein the target layer is a front electrode layer, and the multiple layers under the target layer include a buffer/i-layer, an absorber layer, a back electrode layer, and a substrate, and the linear structure consists of metal grid lines located on the upper surface of the front electrode layer.

12. The method for preparing metal grid lines according to claim 11, wherein the metal grid lines include a metal grid line G1 perpendicular to a P1 line, a P2 line and a P3 line and a metal grid line G2 parallel to and above the P2 line.

13. The method for preparing metal grid lines according to claim 12, wherein
the method for preparing the metal grid line G1 comprises:
G1(1) acquiring the preset positions of the two sides of the metal grid line G1 on the surface of the front electrode, which are denoted as a first side preset position and a second side preset position;
G1(2) producing a plurality of protrusions at intervals along the side length direction at the first side preset position and the second side preset position respectively to form a first protruding line and a second protruding line;
G1(3) applying a liquid-type metallic grid line material between the first protruding line and the second protruding line for deposition to obtain the metal grid line G1 confined between the first protruding line and the second protruding line;
The method for preparing the metal grid line G2 comprises:
G2(1) acquiring the position of the side of the P2 line close to the P3 line on the surface of the front electrode, which is denoted as a third side position;
G2(2) producing a plurality of protrusions at intervals along the side length direction at the third side position to form a third protruding line;
G2(3) applying a liquid-type metallic grid line material in the P2 line for deposition to obtain the metal grid line G2, with the side of the metal grid line G2 close to the P3 line being confined by the third protruding line.

14. The method for preparing metal grid lines according to claim 11, wherein the material of the metal grid lines includes, but is not limited to, metallic ink and dielectric ink.

15. A method for optimizing the aspect ratio of metal grid lines based on the method for preparing metal grid lines based on an improved surface structure of a front electrode according to claim 11, comprising: by controlling the distance between a first protruding line and a second protruding line, the height of protrusions and the amount of metal grid line material, controlling the deposition width and thickness of metal grid lines, so as to control and optimize the aspect ratio of the metal grid lines.

16. A method for preparing a thin-film solar cell based on the method for preparing metal grid lines according to claim 11, comprising the steps of:
sequentially making a substrate, a back electrode layer, an absorber layer, a buffer/i-layer and a front electrode layer of a thin-film solar cell, or sequentially making a substrate, a front electrode layer, a buffer/i-layer, an absorber layer and a back electrode layer of a thin-film solar cell;
after the back electrode layer is made, arranging a P1 line on the back electrode layer; after the buffer/i-layer is made, arranging a P2 line on the absorber layer and the buffer/i-layer; after the front electrode layer is made, arranging a P3 line on the front electrode layer; and carrying out the division and series connection of the large-area thin-film solar cell by means of the P1 line, the P2 line and the P3 line; and
based on the method for preparing metal grid lines according to claim 11, making a metal grid line G1 and a metal grid line G2 on the surface of the front electrode layer far from the buffer layer respectively.

17. A thin film photovoltaic module, it is produced by the method according to claim 16.

18. Use of the solar module according to claim 17 as part of a building envelope, in particular as a window, facade, or roof component.
